(19) United States
(12) Patent Application Publication
(10) Pub. No.: US 2012/0139630 A1
(43) Pub. Date: Jun. 7, 2012

(54) COMPOUND SEMICONDUCTOR DEVICE AND METHOD OF MANUFACTURING THE SAME

(75) Inventors: Shirou OZAKI, Kawasaki (JP); Norikazu Nakamura, Kawasaki (JP); Toshihiro Ohki, Kawasaki (JP); Masahito Kanamura, Kawasaki (JP)

(73) Assignee: FUJITSU LIMITED, Kawasaki (JP)

(21) Appl. No.: 13/280,677

(22) Filed: Oct. 25, 2011

(30) Foreign Application Priority Data
Dec. 3, 2010 (JP) 2010-270795

(51) Int. Cl. H01L 29/78; H02M 3/24; H03F 3/04; H01L 21/28

(52) U.S. Cl. 330/250; 257/330; 438/589; 363/15; 257/E29.262; 257/E21.19

(57) ABSTRACT

On a surface of a compound semiconductor layer including inner wall surfaces of an electrode trench, an etching residue 12a and an altered substance 12b which are produced due to dry etching for forming the electrode trench are removed, and a compound semiconductor is terminated with fluorine. Gate metal is buried in the electrode trench via a gate insulating film, or the gate metal is directly buried in the electrode trench, whereby a gate electrode is formed.

### CROSS-REFERENCE TO RELATED APPLICATION

This application is based upon and claims the benefit of priority of the prior Japanese Patent Application No. 2010-270795, filed on Dec. 3, 2010, the entire contents of which are incorporated herein by reference.

### FIELD

The embodiments discussed herein are directed to a compound semiconductor device and a method of manufacturing the same.

### BACKGROUND

Nitride semiconductor devices have been actively developed as high-withstand-voltage, high-power semiconductor devices, by utilizing their characteristics such as a high saturation electron velocity, a wide band gap, and so on. Many reports have been made on field-effect transistors, in particular, HEMT (High Electron Mobility Transistor) as the nitride semiconductor devices. Especially, an AlGaN/GaN HEMT using GaN as an electron transit layer and using AlGaN as an electron supply layer has been drawing attention. In the AlGaN/GaN HEMT, a distortion ascribable to a difference in lattice constant between GaN and AlGaN occurs in AlGaN. Owing to piezoelectric polarization caused by the distortion and to spontaneous polarization of AlGaN, a high-concentration two-dimensional electron gas (2DEG) is obtained. This makes it possible to realize a high withstand voltage and a high output power.

Patent Document 1: Japanese Laid-open Patent Publication No. 2009-76845

When a gate electrode is formed in the AlGaN/GaN HEMT in a state where a surface of its compound semiconductor layer is altered, a great change in threshold voltage occurs. A possible example of a case where the surface of the compound semiconductor layer is altered is a case where an electrode trench of the gate electrode is formed in the following manner.

What is important in applying the nitride semiconductor device to power supply use is the development of a device that not only is low in loss and high in withstand voltage but also is what is called a normally-off type in which no electric current passes when a gate voltage is off. In the AlGaN/GaN HEMT, owing to a piezoelectric effect being its great characteristic, many electrons exist as 2DEG in the electron transit layer. This effect plays a great role in realizing a high-current operation. On the other hand, when a simple device structure is adopted, the device becomes a normally-on type because many electrons exist in the electron transit layer immediately under a gate even when the gate voltage is off. Therefore, with the aim of increasing the threshold, there has been considered what is called a gate recess structure, that is, to dig gate portions of the electron supply layer (or the electron supply layer and the electron transit layer) by etching to form electrode trenches, thereby reducing the electrons in the electron transit layer.

On the surface of the compound semiconductor layer in which the electrode trenches are formed, in addition to carbon-based residues originating in a resist used for the etching, an altered layer is generated in which a halogen element such as fluorine or chloride originating in etching gas and oxide are contained. It has been newly found out that this altered layer is nitrogen deficient. In the altered layer generated on the surface of the compound semiconductor layer, its nitrogen deficient portion acts as a trap of the electrons. This gives rise to a serious problem that the presence of the altered layer is one of main causes of a great change in the threshold of the device.

### SUMMARY

A compound semiconductor device according to an aspect includes: a compound semiconductor layer; and a gate electrode formed above the compound semiconductor layer, wherein a compound semiconductor on a surface of the compound semiconductor layer is terminated with fluorine.

A method of manufacturing a compound semiconductor device according to an aspect includes: fluorine-treating a surface of a compound semiconductor layer to terminate the surface with fluorine; and forming a gate electrode above the compound semiconductor layer.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A to FIG. 1C are schematic cross-sectional views illustrating a method of manufacturing a MIS-type AlGaN/GaN HEMT according to a first embodiment in order of processes;

FIG. 2A to FIG. 2D, which are continued from FIG. 1A to FIG. 1C, are schematic cross-sectional views illustrating the method of manufacturing the MIS-type AlGaN/GaN HEMT according to the first embodiment in order of processes;

FIG. 3A to FIG. 3C, which are continued from FIG. 2A to FIG. 2C, are schematic cross-sectional views illustrating the method of manufacturing the MIS-type AlGaN/GaN HEMT according to the first embodiment in order of processes;

FIG. 4A to FIG. 4C are characteristic charts presenting results of experiments for confirming effects of the first embodiment;

FIG. 5 is a schematic view illustrating a system having a device structure suitably used in the first embodiment;

FIG. 6 is a schematic cross-sectional view illustrating a main process of a method of manufacturing a Schottky-type AlGaN/GaN HEMT according to a second embodiment;

FIG. 7 is a connection diagram illustrating a schematic structure of a power supply device according to a third embodiment; and

FIG. 8 is a connection diagram illustrating a schematic structure of a high-frequency amplifier according to a fourth embodiment.

### DESCRIPTION OF EMBODIMENTS

Hereinafter, embodiments will be described in detail with reference to the drawings. In the following embodiments, a structure of a compound semiconductor device will be described along with its manufacturing method.

Note that, in the following drawings, some constituent members are not illustrated with relatively accurate size and thickness for convenience of illustration.

### First Embodiment

In this embodiment, a MIS-type AlGaN/GaN HEMT is disclosed as the compound semiconductor device.

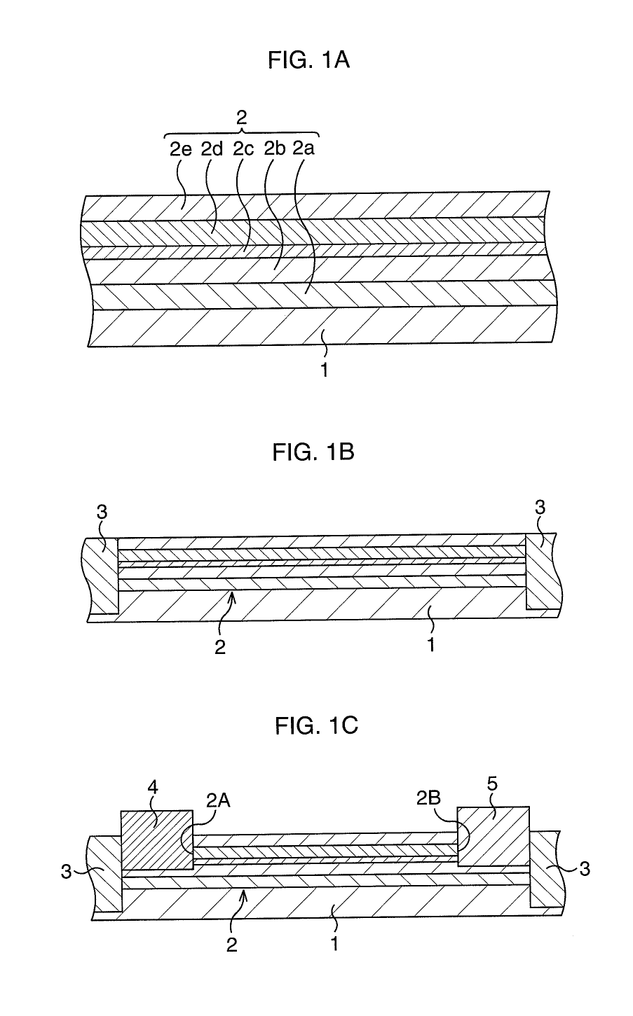

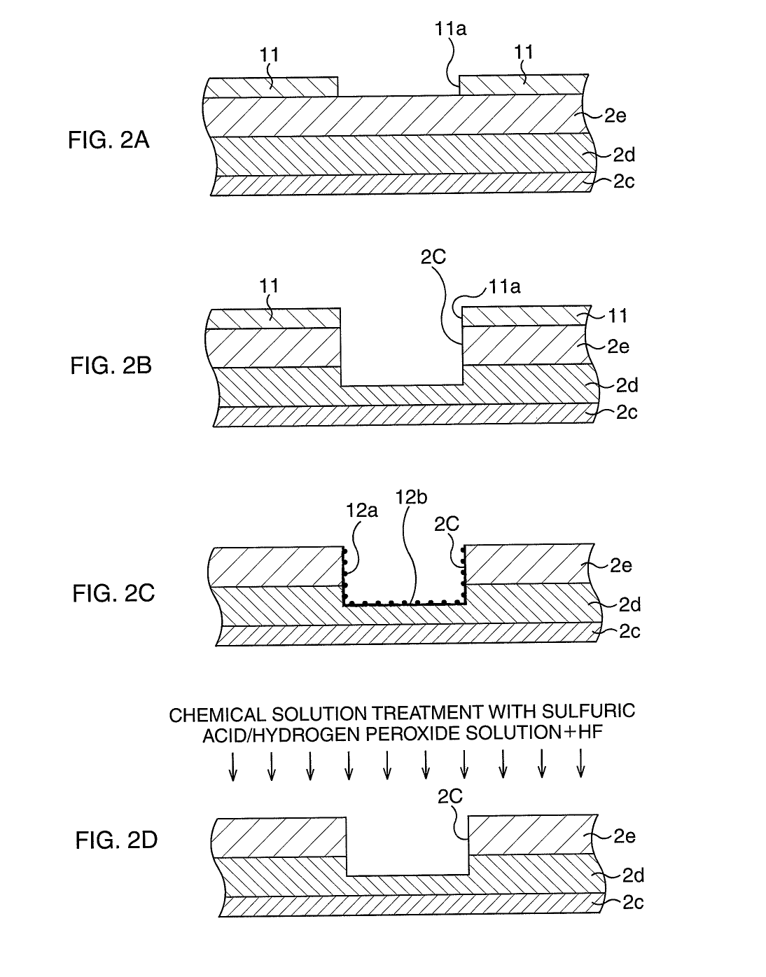

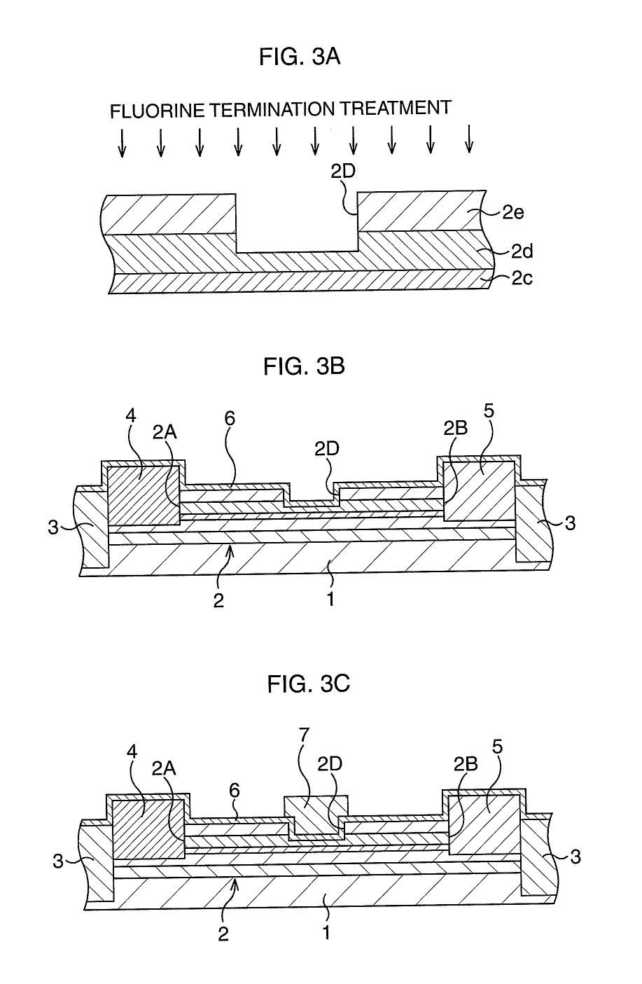

FIG. 1A to FIG. 3C are schematic cross-sectional views illustrating a method of manufacturing the MIS-type AlGaN/GaN HEMT according to the first embodiment in order of processes. For convenience of illustration, in FIG. 2A to FIG. 3A, only the vicinity of a gate electrode is illustrated in an enlarged manner.

First, as illustrated in FIG. 1A, a compound semiconductor layer 2 is formed on, for example, a semi-insulating SiC substrate 1 as a growth substrate. The compound semiconductor layer 2 includes a buffer layer 2a, an electron transit layer 2b, an intermediate layer 2c, an electron supply layer 2d, and a cap layer 2e. In the AlGaN/GaN HEMT, two-dimensional electron gas (2DEG) is generated in the vicinity of an interface, of the electron transit layer 2b, with the electron supply layer 2d (to be exact, the intermediate layer 2c).

More specifically, the following compound semiconductors are grown on the SiC substrate 1 by, for example, a MOVPE (Metal Organic Vapor Phase Epitaxy) method. Instead of the MOVPE method, a MBE (Molecular Beam Epitaxy) method or the like may be used.

On the SiC substrate 1, AlN, i (intentionally undoped)-GaN, i-AlGaN, n-AlGaN, and n-GaN are deposited in sequence to form a stack of the buffer layer 2a, the electron transit layer 2b, the intermediate layer 2c, the electron supply layer 2d, and the cap layer 2e. As a growing condition of AlN, GaN, AlGaN, and GaN, mixed gas of trimethylaluminum gas, trimethylgallium gas, and ammonia gas is used as source gas. Depending on the compound semiconductor layer that is to be grown, whether or not to supply the trimethylaluminum gas as an Al source and the trimethylgallium gas as a Ga source, and their flow rates are appropriately set. A flow rate of the ammonia gas being a common source is set to about 100 ccm to about 10 LM. Further, growth pressure is set to about 50 Torr to about 300 Torr, and growth temperature is set to about 1000° C. to about 1200° C.

In order to grow GaN and AlGaN as an n-type, gas containing, for example, Si as n-type impurities, for example, SiH₄ gas is added to the source gas at a predetermined flow rate, thereby doping GaN and AlGaN with Si. A doping concentration of Si is set to about 1×10¹⁸/cm³ to about 1×10²⁰/cm³, for example, set to about 5×10¹⁸/cm³.

Here, the buffer layer 2a is formed with an about 0.1 μm film thickness, the electron transit layer 2b is formed with an about a 3 μm film thickness, the intermediate layer 2c is formed with an about 5 nm film thickness, and the electron supply layer 2d is formed with an about 20 nm film thickness, with its Al ratio being about 0.2 to about 0.3, and the cap layer 2e is formed with an about 10 nm film thickness.

Subsequently, element isolation structures 3 are formed as illustrated in FIG. 1B.

More specifically, argon (Ar), for instance, is injected to element isolation regions of the compound semiconductor layer 2. Consequently, the element isolation structures 3 are formed in the compound semiconductor layer 2 and in a surface layer portion of the SiC substrate 1. The element isolation structures 3 demarcate an active region on the compound semiconductor layer 2.

Incidentally, instead of the above injection method, a STI (Shallow Trench Isolation) method, for instance, may be used for the element isolation.

Subsequently, as illustrated in FIG. 1C, a source electrode 4 and a drain electrode 5 are formed.

More specifically, electrode trenches 2A, 2B are first formed in portions of the cap layer 2e, the electron supply layer 2d, the intermediate layer 2c, and a surface layer portion of the electron transit layer 2b, which portions are at predetermined source electrode/drain electrode formation positions on the surface of the compound semiconductor layer 2.

A resist mask is formed that has openings at the predetermined source electrode/drain electrode formation positions on the surface of the compound semiconductor layer 2. By using the resist mask, the cap layer 2e, the electron supply layer 2d, the intermediate layer 2c, and the surface layer portion of the electron transit layer 2b are dry-etched to be removed. Consequently, the electrode trenches 2A, 2B are formed. As for an etching condition, inert gas such as Ar and chloride-based gas such as Cl₂ are used as etching gas, and for example, a flow rate of Cl₂ is set to 30 sccm, pressure is set to 2 Pa, and RF making power is set to 20 W.

As an electrode material, Ti/Al is used, for instance. To form the electrodes, an eaves-structure, double-layer resist suitable for a vapor deposition method and a liftoff method is used, for instance. This resist is applied on the compound semiconductor layer 2 to form a resist mask having openings at the positions of the electrode trenches 2A, 2B. Ti/Al is deposited by using this resist mask. A thickness of Ti is about 20 nm and a thickness of Al is about 200 nm. By the liftoff method, the resist mask with the eaves structure and Ti/Al deposited thereon are removed. Thereafter, the SiC substrate 1 is heat-treated at about 550° C. in a nitrogen atmosphere, for instance, and residual Ti/Al is brought into ohmic contact with the electron transit layer 2b. Through the above processes, the source electrode 4 and the drain electrode 5 whose Ti/Al lower portions fill the electrode trenches 2A, 2B are formed.

Subsequently, as illustrated in FIG. 2A, a resist mask 11 to be used for forming an electrode trench of a gate electrode is formed.

More specifically, a resist is applied on the compound semiconductor layer 2 and is processed by lithography, so that an opening 11a is formed at a predetermined gate electrode formation position. Through the above processes, the resist mask 11 from whose opening 11a a surface of the cap layer 2e at the predetermined gate electrode formation position is exposed is formed.

Subsequently, as illustrated in FIG. 2B, an electrode trench 2C is formed at the predetermined gate electrode formation position.

By using the resist mask 11, dry etching is performed for removal so that the cap layer 2e is etched through and part of the electrode supply layer 2d remains. For the dry etching, inert gas such as Ar and fluorine-based gas such as CF₄, CHF₃, C₄F₆, CF₃I, or SF₆ or chloride-based gas such as Cl₂ are used as etching gas. At this time, a thickness of the residual portion of the electron supply layer 2d is about 0 nm to about 20 nm, for example, about 1 nm. Consequently, the electrode trench 2C is formed.

The resist mask 11 is removed by ashing or the like.

Here, as illustrated in FIG. 2C, on inner wall surfaces (a bottom surface and side surfaces) of the electrode trench 2C formed by the dry etching, an etching residue 12a adheres and an altered substance 12b of GaN in the cap layer 2e and AlGaN in the electron supply layer 2d is generated.

In this embodiment, the etching residue 12a and the altered substance 12b are removed by chemical solution treatment as illustrated in FIG. 2D.

More specifically, the chemical solution treatment removes the etching residue 12a and the altered substance 12b in sequence by using, for example, a sulfuric acid/hydrogen peroxide solution for the former and hydrofluoric acid (HF) for the latter. As hydrofluoric acid, diluted hydrofluoric acid with an about 0.01% to about 50% concentration is used. This chemical solution treatment cleans the inner wall surfaces of the electrode trench 2C of the compound semiconductor layer 2.

Subsequently, as illustrated in FIG. 3A, fluorine termination treatment is applied on the surface of the compound semiconductor layer 2.

More specifically, for example, a predetermined plasma processing apparatus plasma-processes the surface of the compound semiconductor layer 2 including the inner wall surfaces of the electrode trench 2C by using fluorine-based gas such as CF₄ or SF₆. The plasma processing is continued for one minute, for instance, under processing conditions that the fluorine-based gas, for example, CF₄ is used, its flow rate is 200 sccm, pressure is 10 Pa, and RF making power is 60 W.

In this embodiment, applying only the chemical solution treatment with the sulfuric acid/hydrogen peroxide solution would result in the removal of only the etching residue 12a from the inner wall surfaces of the electrode trench 2C. In this case, the altered substance 12b would remain on the inner wall surfaces of the electrode trench 2C. More specifically, in the generated altered substance 12b, a mixture layer of the compound semiconductor (for example, GaN) and an oxide (for example, GaOₓ) of the compound semiconductor is stacked with a layer of a product produced from the reaction of fluorine (F) with an etching gas species (for example, Cl) and with carbon (C) of the resist. Here, on the surface of the compound semiconductor layer 2 including the inner wall surfaces of the electrode trench 2C under the mixture layer, a dangling bond is present.

In this embodiment, after the removal of the etching residue 12a, the altered substance 12b is removed by the chemical solution treatment. In this state, the surface of the compound semiconductor layer 2 where the dangling bond is present is exposed, with the aforesaid mixture layer and the reaction product layer being removed. Subsequently, in this state, the aforesaid fluorine termination treatment follows. Consequently, on the surface of the compound semiconductor layer 2, the dangling bond of the compound semiconductor is directly terminated with fluorine (F), so that a F-terminated surface 2D is formed.

Here, instead of performing the fluorine plasma processing in FIG. 3A after the chemical solution treatment in FIG. 2D, the fluorine termination treatment in FIG. 3A may be performed concurrently in the hydrofluoric acid treatment in the chemical solution treatment in FIG. 2D.

In this case, in the chemical solution treatment in FIG. 2D, the hydrofluoric acid treatment uses hydrofluoric acid with a high concentration, for example, about 50% concentration. Consequently, the altered substance 12b is removed and at the same time, the dangling bond on the surface of the compound semiconductor layer 2 including the inner wall surfaces of the electrode trench 2C is terminated with fluorine (F), so that the F-terminated surface 2D is formed as in the above-described case. This method is capable of performing the fluorine termination treatment in the same process as the removal of the altered substance 12b, which also contributes to a reduction in the number of processes.

After the above-described fluorine termination treatment (the plasma processing, the chemical solution treatment using high-concentration hydrofluoric acid, or the like), the surface of the compound semiconductor layer 2 is washed with water or water vapor. Consequently, fluorine (F) excessively bonded with or adhering on the surface of the compound semiconductor layer 2 is removed, so that the desired F-terminated surface 2D is obtained.

Subsequently, as illustrated in FIG. 3B, a gate insulating film 6 is formed.

More specifically, an insulating material, for example, Al₂O₃, is deposited on the compound semiconductor layer 2 so as to cover the inner wall surfaces of the electrode trench 2C which are turned into the F-terminated surface 2D, thereby forming the gate insulating film 6. Al₂O₃ is deposited by, for example, an ALD (Atomic Layer Deposition) method, with an about 5 nm to about 100 nm film thickness, here, with an about 40 nm film thickness.

Instead of the ALD method, a CVD method or the like may be used for the deposition of Al₂O₃, for example. Further, in forming the gate insulating film, instead of depositing Al₂O₃, a nitride or an oxynitride of Al, an oxide, a nitride, or an oxynitride of silicon (Si), or an oxide, a nitride, or an oxynitride of hafnium (Hf) may be deposited, or those selected from the above may be deposited in multilayer.

Subsequently, as illustrated in FIG. 3C, a gate electrode 7 is formed.

More specifically, first, a lower resist (for example, product name PMGI: manufactured by MicroChem USA) and an upper resist (for example, product name PFI32-A8: manufactured by Sumitomo Chemical Co., Ltd.) are applied and formed on the gate insulating film 6 by, for example, a spin coating method. An opening with, for example, about 0.8 μm diameter is formed in the upper resist by ultraviolet exposure. Next, with the upper resist used as a mask, the lower resist is wet-etched with an alkaline developing solution. Next, with the upper resist and the lower resist used as masks, gate metal (Ni: about 10 nm film thickness/Au: about 300 nm film thickness) is vapor-deposited on the entire surface including the inside of the opening. Thereafter, by liftoff using a warmed organic solvent, the lower resist, the upper resist, and the gate metal on the upper resist are removed. Consequently, the gate electrode 7 part of whose gate metal fills the inside of the electrode trench 2C via the gate insulating film 6 is formed.

Thereafter, through processes such as the formation of a protection film and the formation of the source electrode 4, the drain electrode 5, and contacts of the gate electrode 7, the MIS-type AlGaN/GaN HEMT is formed.

Experiments for confirming effects of the AlGaN/GaN HEMT according to this embodiment based on the comparison with a comparative example were conducted.

Experiment results are presented below. As presented in Table 1 below, in “examples 1, 2” of this embodiment, the plasma processing is adopted as the fluorine termination treatment and the hydrofluoric acid concentration in the fluorine treatment prior to the fluorine termination treatment is set to 5% and 10% respectively. Further, in “an example 3”, the hydrofluoric acid treatment with high-concentration hydrofluoric acid is adopted for the removal of the altered substance 12b and the fluorine termination treatment, and the hydrofluoric acid concentration is set to 50%. In “a conventional art” as the comparative example, used is an AlGaN/GaN HEMT that is formed without undergoing the hydrofluoric acid treatment and the fluorine termination treatment of this embodiment (with the dangling bond being left present on the surface of the compound semiconductor layer 2).

TABLE 1

| | | | fluorine |
|---|---|---|---|
| | | | termination |
| | wash 1 | wash 2 | treatment |
| Conventional | sulfuric | water | — |
| art | acid/hydrogen | | |
| | peroxide | | |
| | solution | | |
| example 1 | sulfuric | hydrofluoric | CF₄ plasma |
| | acid/hydrogen | acid (5%)→ | |
| | peroxide | water | |
| | solution | | |
| example 2 | sulfuric | hydrofluoric | CF₄ plasma |
| | acid/hydrogen | acid (10%)→ | |
| | peroxide | water | |
| | solution | | |
| example 3 | sulfuric | hydrofluoric | *finished at |
| | acid/hydrogen | acid (50%)→ | wash 2 |
| | peroxide | water | |
| | solution | | |

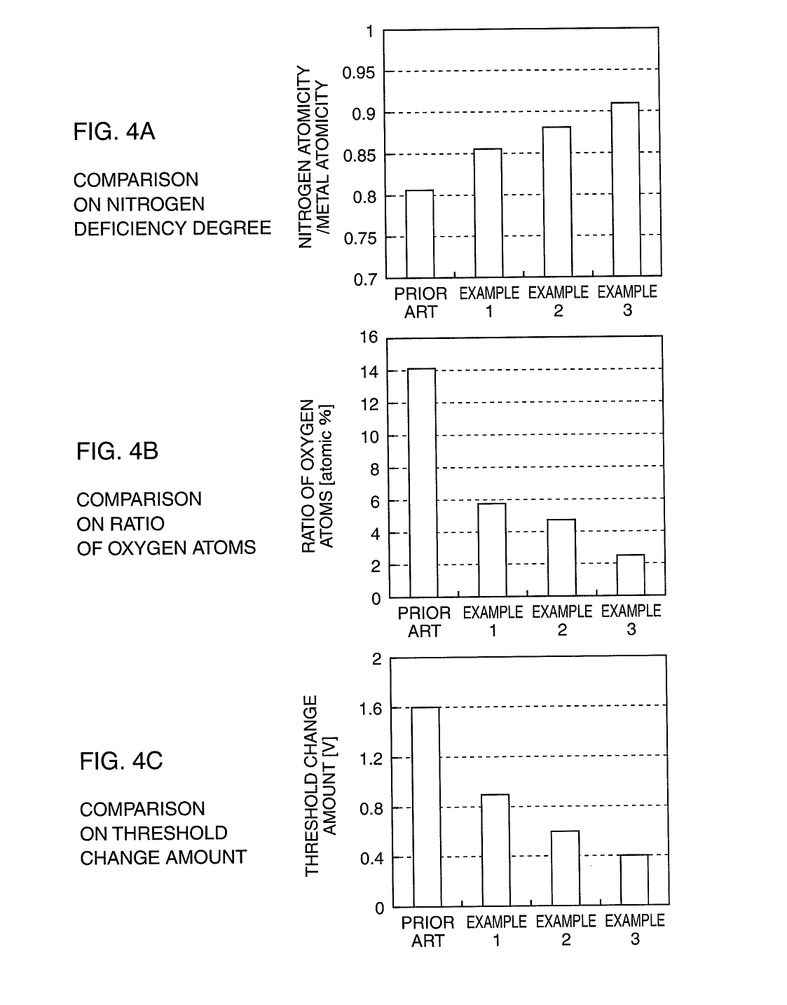

In the experiment 1, a degree of nitrogen deficiency on the surface of the compound semiconductor layer 2 was studied by using XPS (X-ray Photoelectron Spectroscopy). In the experiment 2, a ratio of oxygen atoms to the total atomicity on the surface of the compound semiconductor layer 2 was studied by using XPS. The oxygen atoms are oxygen existing in the aforesaid mixture layer of the altered substance 12b. In the experiment 3, a change amount of the threshold was studied. The results of the experiment 1, the results of the experiment 2, and the results of the experiment 3 are presented in FIG. 4A, FIG. 4B, and FIG. 4C respectively.

The results of the experiment 1 will be described. As presented in FIG. 4A, in “the conventional art”, a value of nitrogen atomicity/metal (here Ga) atomicity is small, that is, the degree of the nitrogen deficiency is large. On the other hand, in “the example 1”, the value of nitrogen atomicity/metal atomicity is as large as about 0.85, that is, the degree of the nitrogen deficiency is small. It is seen that the degree of the nitrogen deficiency becomes smaller in order of “the examples 1, 2, 3”. In particular, in the example 3, it is confirmed that the degree of the nitrogen deficiency improves up to a state where almost no nitrogen deficiency exists.

The results of the experiment 2 will be described. As presented in FIG. 4B, the ratio of the oxygen atoms is large in “the conventional art”, but is about 6% or less in “the example 1”. It is seen that the ratio of the oxygen atoms becomes smaller in order of “the examples 1, 2, 3”. In particular, in the example 3, the ratio improves up to a state where almost no oxygen atoms exists.

Based on the results of the experiments 1, 2, the results of the experiment 3 will be described. As presented in FIG. 4C, in “the conventional art”, a great change in the threshold voltage by about 1.6 V is observed. On the other hand, it is seen that, in “the example 1”, a change amount of the threshold voltage reduces to about a half the value of “the conventional art” and the change amount becomes smaller in order of “the examples 1, 2, 3”. In particular, in the example 3, it is confirmed that the change amount improves up to a state where almost no change in the threshold voltage occurs.

The results of the experiment 1 lead to the understanding that in this embodiment, the value of nitrogen atomicity/metal atomicity on the surface of the compound semiconductor layer 2 may be set to not less than 0.85 nor more than 1. When this value is less than 0.85, the change amount of the threshold voltage becomes normegligibly large. On the other hand, if this value is 1, the bond between Ga and N is perfect, which is an ideal state. From the above, it is confirmed that the change in the threshold voltage is fully reduced when the value of nitrogen atomicity/metal atomicity is not less than 0.85 nor more than 1.

The results of the experiment 2 lead to the understanding that in this embodiment, the ratio of the oxygen atoms on the surface of the compound semiconductor layer 2 may be set to not less than 2% nor more than 6%. When this ratio is more than 6%, it is thought that the change amount of the threshold voltage becomes normegligibly large.

Incidentally, in the examples 1 to 3 in the experiment 2, the SiC substrate is exposed to the atmosphere after the fluorine termination treatment. It is thought that the surface of the compound semiconductor layer 2 is as a result slightly oxidized. It is thought that the ratio of the oxygen atoms increases by about 2% due to the oxidization ascribable to the exposure to the atmosphere. Therefore, in the results of the experiment 2, the detected ratio of the oxygen atoms is larger by about 2%. Considering this fact, in this embodiment, it is possible to define a lower limit value of the ratio of the oxygen atoms on the surface of the compound semiconductor layer 2 to (2%−2%=) 0%, which is an ideal state. From the above, it is seen that the change in the threshold voltage is fully reduced when the aforesaid ratio of the oxygen atoms is set to not less than 0% nor more than 6%.

Incidentally, in order to obtain results equivalent to those of the experiment 3 regarding a ratio of carbon (C) existing in the aforesaid reaction product layer of the altered substance 12b (a ratio of C on the surface of the compound semiconductor layer 2), the ratio of C is set smaller than a ratio of F on the surface of the compound semiconductor layer 2. For example, the ratio of C may be set to about 4% or less. Consequently, the change in the threshold voltage is fully reduced.

In this embodiment, for example, the chemical solution treatment, the fluorine termination treatment (the above-described plasma processing, high-concentration hydrofluoric acid chemical solution treatment serving also as the chemical solution treatment, or the like), and the subsequent processing (the formation of the gate insulating film and so on) may be performed in situ.

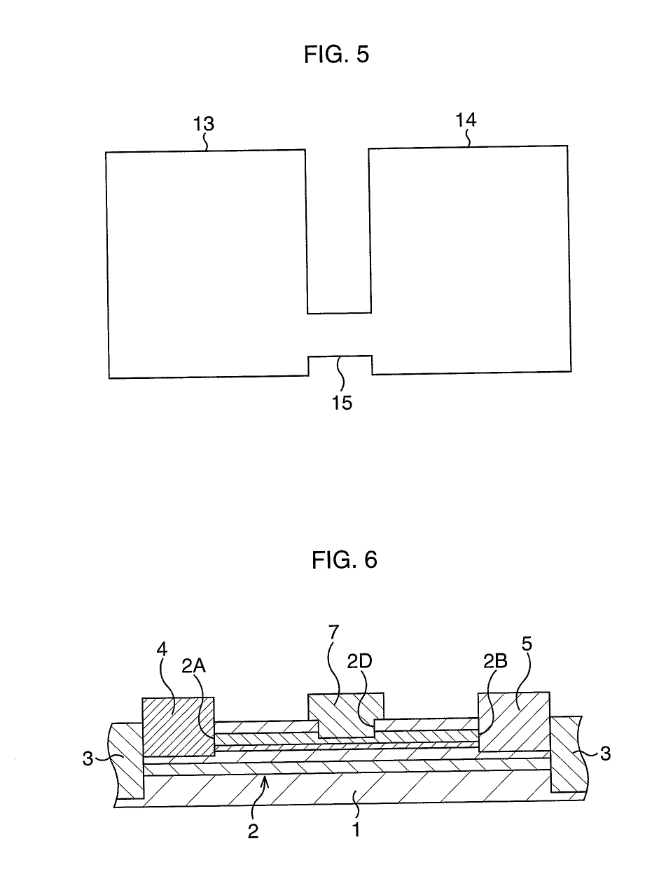

An example thereof is illustrated in FIG. 5. In a system with the device structure in FIG. 5, a first environment 13 and a second environment 14 are provided. The first environment 13 is a device structure which is insulated from the outside air and in which the chemical solution treatment and the plasma processing being the fluorine termination treatment (or the chemical solution treatment serving also as the fluorine termination treatment) are performed. The second environment 14 is a device structure which is insulated from the outside air and includes an ALD apparatus for forming the gate insulating film. In this system, the first environment 13 and the second environment 14 are connected to each other by a coupling part 15 while insulated from the outside air. The use of the system with the device structure thus kept in situ for the chemical solution treatment, the fluorine termination treatment, and the formation of the gate insulating film prevents the oxidation ascribable to the atmospheric exposure, which makes it possible to make the ratio of the oxygen atoms on the surface of the compound semiconductor layer approximate the 0% ideal state. This can further reduce the change in the threshold voltage in the AlGaN/GaN HEMT.

As described hitherto, this embodiment realizes a highly reliable AlGaN/GaN HEMT capable of providing a high transistor characteristic, with the dangling bond on the surface of its compound semiconductor layer 2 being surely reduced and accordingly with its threshold voltage undergoing less change and being stable.

### Second Embodiment

In this embodiment, a Schottky-type AlGaN/GaN HEMT is disclosed as the compound semiconductor device.

FIG. 6 is a schematic cross-sectional view illustrating a main process of a method of manufacturing the Schottky-type AlGaN/GaN HEMT according to the second embodiment.

First, as in the first embodiment, the processes in FIG. 1A to FIG. 3A are executed to apply the fluorine termination treatment on a surface of a compound semiconductor layer 2.

Subsequently, as illustrated in FIG. 6, a gate electrode 7 is formed.

More specifically, first, a lower resist (for example, product name PMGI: manufactured by MicroChem USA) and an upper resist (for example, product name PFI32-A8: manufactured by Sumitomo Chemical Co., Ltd.) are applied and formed on the compound semiconductor layer 2 by, for example, a spin coating method. An opening with, for example, about 0.8 μm diameter is formed in the upper resist by ultraviolet exposure. Next, with the upper resist used as a mask, the lower resist is wet-etched with an alkaline developing solution. Next, with the upper resist and the lower resist used as masks, gate metal (Ni: about 10 nm film thickness/Au: about 300 nm film thickness) is vapor-deposited on the entire surface including the inside of the opening. Thereafter, by liftoff using a warmed organic solvent, the lower resist, the upper resist, and the gate metal on the upper resist are removed. Consequently, the gate electrode 7 part of whose gate metal fills the inside of an electrode trench 2C is formed.

Thereafter, through processes such as the formation of a protection film and the formation of a source electrode 4, a drain electrode 5, and contacts of the gate electrode 7, the Schottky-type AlGaN/GaN HEMT is formed.

As described above, this embodiment realizes a highly reliable AlGaN/GaN HEMT capable of providing a high transistor characteristic, with a dangling bond on a surface of its compound semiconductor layer 2 being surely reduced and accordingly with its threshold voltage undergoing less change and being stable.

### Third Embodiment

In this embodiment, a power supply device including the AlGaN/GaN HEMT of one kind selected from the first and second embodiments is disclosed.

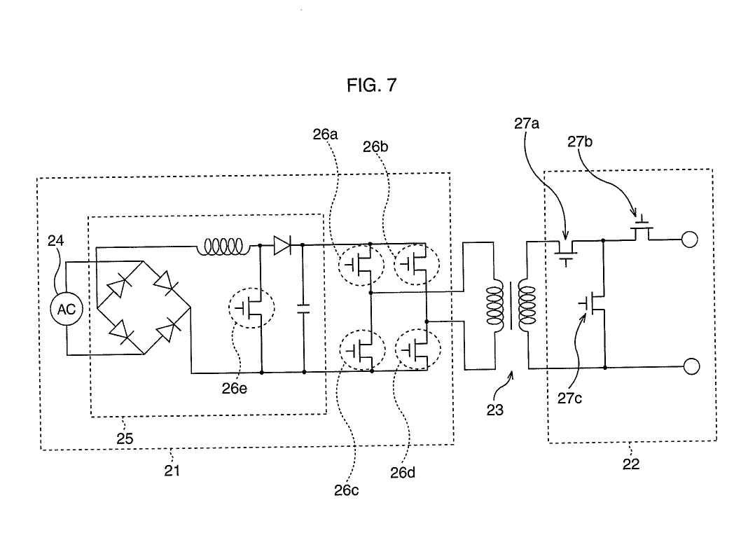

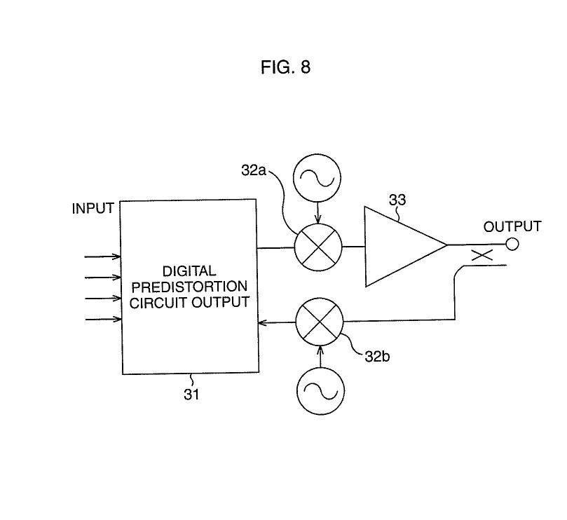

FIG. 7 is a connection diagram illustrating a schematic structure of the power supply device according to the third embodiment.

The power supply device according to this embodiment includes: a high-voltage primary circuit 21, a low-voltage secondary circuit 22; and a transistor 23 disposed between the primary circuit 21 and the secondary circuit 22.

The primary circuit 21 includes an AC power supply 24, what is called a bridge rectifier circuit 25, and a plurality of (here, four) switching elements 26a, 26b, 26c, 26d. Further, the bridge rectifier circuit 25 has a switching element 26e.

The secondary circuit 22 includes a plurality of (here, three) switching elements 27a, 27b, 27c.

In this embodiment, the switching elements 26a, 26b, 26c, 26d, 26e of the primary circuit 21 are each the AlGaN/GaN HEMT of one kind selected from the first and second embodiments. On the other hand, the switching elements 27a, 27b, 27c of the secondary circuit 22 are each an ordinary MIS-FET using silicon.

In this embodiment, the highly reliable AlGaN/GaN HEMT capable of providing a high transistor characteristic, with the dangling bond on the surface of its compound semiconductor layer 2 being surely reduced and accordingly with its threshold voltage undergoing less change and being stable, is applied to the high-voltage circuit. Consequently, a power supply circuit that has a high power and is highly reliable is realized.

### Fourth Embodiment

In this embodiment, a high-frequency amplifier including the AlGaN/GaN HEMT of one kind selected from the first and second embodiments is disclosed.

FIG. 8 is a connection diagram illustrating a schematic structure of the high-frequency amplifier according to the fourth embodiment.

The high-frequency amplifier according to this embodiment includes a digital predistortion circuit 31, mixers 32a, 32b, and a power amplifier 33.

The digital predistortion circuit 31 compensates a nonlinear distortion of an input signal. The mixer 32a mixes the input signal whose nonlinear distortion is compensated and an AC signal. The power amplifier 33 amplifies the input signal mixed with the AC signal and has the AlGaN/GaN HEMT of one kind selected from the first and second embodiments. Note that in the structure in FIG. 8, the mixer 32b is capable of mixing an output-side signal with an AC signal according to, for example, the switching of a switch and sending the mixed signal to the digital pre-distortion circuit 31.

In this embodiment, the highly reliable AlGaN/GaN HEMT capable of providing a high transistor characteristic, with the dangling bond on the surface of its compound semiconductor layer 2 being surely reduced and accordingly with its threshold voltage undergoing less change and being stable, is applied to the high-frequency amplifier. Consequently, a high-frequency amplifier that has a high withstand voltage and thus is highly reliable is realized.

### Other Embodiments

In the first to fourth embodiments, the AlGaN/GaN HEMT is taken as an example of the compound semiconductor device. The compound semiconductor device is also applicable to the following HEMTs besides the AlGaN/GaN HEMT.

### Example 1 of Other HEMT

In this example, an InAlN/GaN HEMT is disclosed as the compound semiconductor device.

InAlN and GaN are compound semiconductors whose lattice constants can be close to each other by their compositions. In this case, in the above-described first to fourth embodiments, the electron transit layer is made of i-GaN, the intermediate layer is made of i-InAlN, the electron supply layer is made of n-InAlN, and the cap layer is made of n-GaN. Further, because almost no piezoelectric polarization occurs in this case, two-dimensional electron gas is mainly generated by spontaneous polarization of InAlN.

According to this example, realized is a highly reliable InAlN/GaN HEMT capable of providing a high transistor characteristic, with a dangling bond on a surface of its compound semiconductor layer being surely reduced and accordingly with its threshold voltage undergoing less change and being stable, similarly to the aforesaid AlGaN/GaN HEMT.

### Example 2 of Other HEMT

In this example, an InAlGaN/GaN HEMT is disclosed as the compound semiconductor device.

GaN and InAlGaN are compound semiconductors, the latter being smaller in lattice constant than the former. In this case, in the above-described first to fourth embodiments, the electron transit layer is made of i-GaN, the intermediate layer is made of i-InAlGaN, the electron supply layer is made of n-InAlGaN, and the cap layer is made of n+-GaN.

According to this example, realized is a highly reliable InAlGaN/GaN HEMT capable of providing a high transistor characteristic, with a dangling bond on a surface of its compound semiconductor layer being surely reduced and accordingly with its threshold voltage undergoing less change and being stable.

According to the above-described embodiments, realized is a highly reliable compound semiconductor device capable of providing a high transistor characteristic, with a dangling bond on a surface of its compound semiconductor layer being surely reduced and accordingly with its threshold voltage undergoing less change and being stable.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A compound semiconductor device comprising:
a compound semiconductor layer; and
a gate electrode formed above the compound semiconductor layer,
wherein a compound semiconductor on a surface of the compound semiconductor layer is terminated with fluorine.

2. The compound semiconductor device according to claim 1,
wherein a ratio of nitrogen atomicity and metal atomicity on the surface of the compound semiconductor layer is not less than 0.84 nor more than 1.

3. The compound semiconductor device according to claim 1,
wherein a ratio of oxygen atomicity to a total atomicity on the surface of the compound semiconductor layer is not less than 0% nor more than 6%.

4. The compound semiconductor device according to claim 1,
wherein the gate electrode is formed to be partly buried in a trench formed in the compound semiconductor layer.

5. The compound semiconductor device according to claim 1,
wherein the gate electrode is formed above the compound semiconductor layer via a gate insulating film, and
wherein the gate insulating film contains an oxide, a nitride, or an oxynitride selected from silicon, aluminum or hafnium or any combination thereof.

6. A method of manufacturing a compound semiconductor device, comprising:
fluorine-treating a surface of a compound semiconductor layer to terminate the surface with fluorine; and
forming a gate electrode above the compound semiconductor layer.

7. The method of manufacturing the compound semiconductor device according to claim 6, further comprising:
forming a trench in the surface of the compound semiconductor layer; and
wet-etching an inside of the trench with a chemical solution after the formation of the trench, and
wherein the fluorine treatment is performed after the wet-etching.

8. The method of manufacturing the compound semiconductor device according to claim 6, further comprising
forming a trench in the surface of the compound semiconductor layer,
wherein, after the formation of the trench, by wet-etching an inside of the trench with high-concentration hydrofluoric acid, the inside of the trench is washed and the fluorine treatment is performed.

9. The method of manufacturing the compound semiconductor device according to claim 6,
wherein, after the fluorine treatment, the surface of the compound semiconductor layer is washed with water or water vapor.

10. The method of manufacturing the compound semiconductor device according to claim 6,
wherein a ratio of nitrogen atomicity and metal atomicity on the surface of the compound semiconductor layer is not less than 0.84 nor more than 1.

11. The method of manufacturing the compound semiconductor device according to claim 6,
wherein a ratio of oxygen atomicity to total atomicity on the surface of the compound semiconductor layer is not less than 0% nor more than 6%.

12. The method of manufacturing the compound semiconductor device according to claim 6,
wherein the gate electrode is formed above the compound semiconductor layer via a gate insulating film, and
wherein the gate insulating film contains an oxide, a nitride, or an oxynitride selected from silicon, aluminum or hafnium or any combination thereof.

13. A power supply circuit comprising:
a transformer; and
a high-voltage circuit and a low-voltage circuit sandwiching the transformer,
wherein the high-voltage circuit comprises a transistor, the transistor comprising:
a compound semiconductor layer; and
a gate electrode formed above the compound semiconductor layer,
wherein a compound semiconductor on a surface of the compound semiconductor layer is terminated with fluorine.

14. A high-frequency amplifier amplifying an input high-frequency voltage to output the amplified high-frequency voltage, the high-frequency amplifier comprising
a transistor, the transistor comprising:
a compound semiconductor layer; and
a gate electrode formed above the compound semiconductor layer,
wherein a compound semiconductor on a surface of the compound semiconductor layer is terminated with fluorine.
